(19) United States
(12) Patent Application Publication
(10) Pub. No.: US 2002/0068435 A1
(43) Pub. Date: Jun. 6, 2002

(54) Method for removing carbon-rich particles adhered on the exposed copper surface of a copper/low k dielectric dual damascene structure

(75) Inventors: Teng-Chun Tsai, Hsin-Chu City (TW); Chia-Lin Hsu, Taipei City (TW); Yung-Tsung Wei, Pai-Ho Chen (TW); Ming-Sheng Yang, Hsin-Chu City (TW)

Correspondence Address: LOWE HAUPTMAN GILMAN & BERNER, LLP, Suite 310, 1700 Diagonal Road, Alexandria, VA, 22314, US

(73) Assignee: UNITED MICROELECTRONICS CORP.

(21) Appl. No.: 09/729,201

(22) Filed: Dec. 5, 2000

(51) Int. Cl. H01L 21/4763; H01L 21/302; H01L 21/461; H01L 21/311

(52) U.S. Cl. 438/637; 438/691; 438/694; 438/697; 438/699; 438/703; 438/687

(57) ABSTRACT

A method for removing carbon-rich particles adhered on the exposed copper surface of a copper/low k dielectric dual damascene structure is provided. A barrier layer and a barrier-CMP stopping layer are formed between the copper layer and the low k dielectric layer of the dual damascene structure. After a Cu-CMP process and a barrier CMP process are completed, a chemical buffing polishing process using a basic solution under a downward force of about 0.5 to 3 psi is performed to remove carbon-rich particles adhered on the exposed copper surface due to the low k dielectric having at least 90% carbon element being exposed and then polished during the Cu-CMP process and the barrier CMP process, which results from a dishing phenomenon of the copper layer occurring during the two CMP processes. Finally, a post chemical mechanical polishing cleaning process is performed to remove away dirt left on the exposed copper surface.

### BACKGROUND OF THE INVENTION

1. Field of the Invention

The present invention relates to a semiconductor process. More particularly, the present invention relates to a method for removing carbon-rich particles adhered on the exposed copper surface of a copper/low k dielectric dual damascene structure.

2. Description of the Prior Art

When the semiconductor process steps into the stage of deep-submicron, it is a trend to employ a Cu damascene process combined with a low k material as an interlayer dielectric to effectively reduce RC delay and improve electromigration property. FIG. 1A shows a typical copper/low k dielectric dual damascene structure. A semiconductor substrate 100 having a substructure comprising devices formed in the substrate and a metal layer formed thereon (not shown in the figure) is provided. And, a barrier-CMP stopping layer 104 formed of silicon nitride (Si₃N₄)/or silicon carbide and a barrier layer 106 of Ta/or TaN are inter-layers between a low k dielectric layer 102 formed on the substrate 100 and a copper layer 108. The barrier layer 106 is served for preventing copper diffusion to the low k dielectric layer 102.

Referring to FIG. 1B, during the copper/low k dielectric dual damascene process, a copper chemical mechanical polishing process is firstly applied to planarize the copper layer 108 inlaid into the trench 112 and via hole 110 structures of the low k dielectric layer 102, until the barrier layer 106. Then, a barrier chemical mechanical polishing process is followed to remove the barrier layer 106 until the stopping layer 104. However, the softer copper metal typically polishes back at a faster rate than the surrounding material and then causing dishing in the copper layer 108, as shown in FIG. 1B, the CMP copper layer 108 is provided with a dished structure below the dotted line of the top surface thereof. The low k dielectric layer 102 is easily exposed and then polished during the two CMP processes, due to the dishing phenomenon of the copper layer 108, even though the barrier-CMP stopping layer 104 is applied on the low k dielectric layer 102. The low k dielectric generally carbon-rich, containing at least 90% carbon element, and copper metal and carbon element have reverse electricity in a neutral/or acidic slurry employed in the copper CMP and barrier CMP processes. Therefore, there are many carbon-rich particles produced and adhered on the exposed copper surface of the copper layer 108 inlaid into the trench 112 and the via hole 110, during the two CMP processes, which results in a process defect.

Accordingly, it is desirable to provide a method for effectively remove carbon-rich particles adhered on the exposed copper surface of a copper/low k dielectric dual damascene structure, and then alleviate the drawback of the conventional CMP process for copper/low k dielectric damascene process.

### SUMMARY OF THE INVENTION

It is one object of the present invention to provide a method for removing carbon-rich particles adhered on the exposed copper surface of a copper/low k dielectric dual damascene structure. After a Cu-CMP process and barrier CMP process are completed, a chemical buffing polishing process under a downward force of about 0.5 to 3 psi, using a basic solution, is performed on the exposed copper surface to effectively remove carbon-rich particles adhered thereon, which is due to the low k dielectric layer containing at least 90% carbon element being exposed and then polished during the two CMP processes, coming from a dishing phenomenon of the copper layer.

It is another object of the present invention to provide a method for effectively removing carbon-rich particles adhered on the exposed copper surface of a copper/low k dielectric dual damascene structure, which is suitably applied to a low k material chemical mechanical polishing process.

In order to achieve the above objects, the present invention provides a method for removing carbon-rich particles adhered on the exposed copper surface of a copper/low k dielectric dual damascene structure. Firstly, providing a semiconductor substrate having a substructure comprising devices formed in the substrate and a metal layer formed thereon. Then, forming a low k dielectric layer over the substrate. Subsequently, forming a stopping layer on the low k dielectric layer. Thereafter, patterning the stopping layer and the low k dielectric layer to form a plurality of via holes for interconnects, and then patterning the stopping layer and the low k dielectric layer to form a plurality of trenches for conductive lines. Afterward, forming a conformal blanket layer above the patterned layer of the stopping layer and the low k dielectric layer as a barrier layer. Following, forming a copper layer over the barrier layer to fill the via hole and the trench. Then, performing a first chemical mechanical polishing process to planarize the copper layer until the barrier layer. Subsequently, performing a second chemical mechanical polishing process to remove the barrier layer until the stopping layer, and thereby the copper/low k dielectric dual damascene structure is formed. Afterward, performing a chemical buffing polishing process under a downward force of about 0.5 to 3 psi using a basic solution to remove the carbon-rich particles adhered on the exposed copper surface of the copper layer filled in the trench and the via hole. Finally, performing a post chemical mechanical polishing cleaning process to remove away dirt left on the exposed copper surface.

### BRIEF DESCRIPTION OF THE DRAWINGS

The present invention can be best understood through the following description and accompanying drawings wherein:

FIG. 1A depicts a schematic cross sectional view of a conventional copper/low k dielectric dual damascene structure;

FIG. 1B depicts a schematic cross sectional view of the conventional copper/low k dielectric dual damascene structure after a Cu-CMP process and barrier CMP process, in which a dishing phenomenon of the exposed copper surface occurs; and

FIG. 2 depicts a flow diagram of the processes of a method according one embodiment of the present invention.

### DESCRIPTION OF THE PREFERRED EMBODIMENT

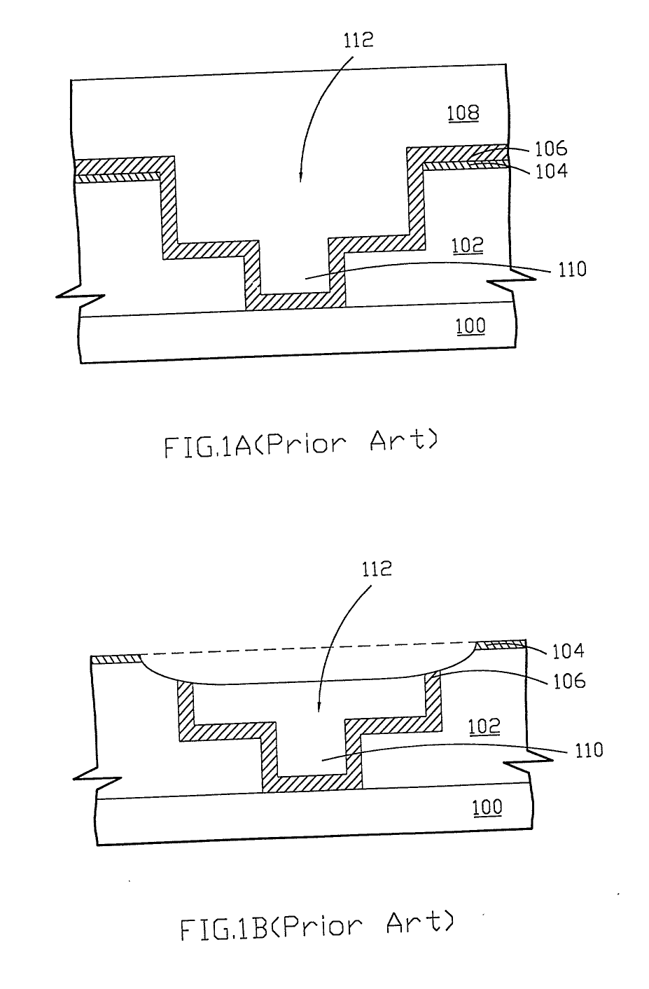

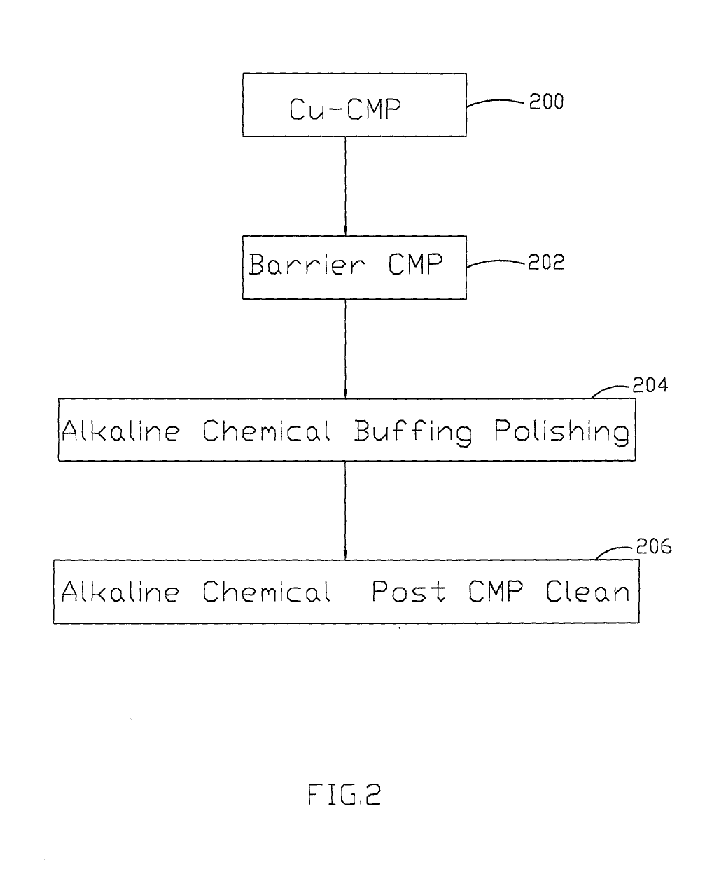

FIG. 1B illustrates a general copper/low k dielectric damascene structure. The substrate 100 is a semiconductor substrate having a substructure comprising devices formed in the substrate 100 and a metal layer formed thereon (not shown in the figure). The low k dielectric layer 102 is carbon-rich, containing at least 90% carbon element, and can formed of spin-on polymer, such as aromatic hydrocarbons, silk and flare. The low k dielectric layer 102 is shown with a trench 112 and a via hole 110 pattern. The barrier layer 106 is typically a Ta or TaN layer act as a liner layer for the trench 112 and the via hole 110 for preventing copper diffusion to the low k dielectric layer 102. A protection layer formed of silicon nitride/or silicon carbide on the low k dielectric layer 102 is served as the stopping layer 104 for the barrier layer's chemical mechanical polishing process. CMP Cu metal is shown with a dished structure below the dotted line of the top surface of the copper layer 108.

The barrier layer 106 of Ta/or TaN is a blanket layer conformally covering surfaces both inside and out the trench 112 and via hole 110 area. The physical vapor deposition (PVD) technique is a preferred method for the considerations of low film stress, good coverage and good adhesion.

The copper layer 108 fills into the trench 112 and via hole 110, and can be deposited using PVD, CVD, or electroplating. Typically, the copper deposition thickness can range from 1 um to several microns.

In the usual method of dual damascene, the low k dielectric layer 108 is patterned twice by the conventional photolithography and etching method. One forms the via hole 110 for interconnect and then the second forms the trench 112 for the conductive line, such as a copper line, in the low k dielectric layer 102.

After the copper layer 108 is deposited over the barrier layer 106, a first chemical mechanical polishing process 200 is performed to planarize the copper layer 108 until the barrier layer 106. Then, a second chemical mechanical polishing process 202 is followed to remove the barrier layer 106 until the stopping layer 104. As shown in FIG. 1B, during these two CMP processes, the low k dielectric layer 102 is easily exposed and then polished due to the dishing phenomenon of the copper layer 108, as described above. And then, there are many carbon-rich particles produced and adhered on the exposed copper surface, which results in a defect in the dual damascene process. Therefore, a chemical buffing polishing process, such as an alkaline chemical buffing polishing process 204, is applied to remove the carbon-rich particles adhered on the exposed copper surface under a downward force of about 0.5 to 3 psi and by way of a chemical reaction. The chemical buffing process can be performed using a basic solution, such as an alkaline basic solution with a pH about 8 to 12, preferably about 10. Finally, a post CMP clean process, such as an alkaline chemical post CMP clean process 206 is applied to remove dirt left on the exposed copper surface. The post CMP clean process can be performed using a basic solution, such as an alkaline basic solution containing an organic amine compound and a quaternary ammonium hydroxide compound.

The preferred embodiment is only used to illustrate the present invention, not intended to limit the scope thereof. Many modifications of the preferred embodiment can be made without departing from the spirit of the present invention.

What is claimed is:

1. A method for removing carbon-rich particles adhered on the exposed copper surface of a copper/low k dielectric dual damascene structure, said method comprising:
providing a semiconductor substrate having a substructure comprising devices formed in said substrate and a metal layer formed thereon;
forming a low k dielectric layer over said substrate;
forming a stopping layer on said low k dielectric layer;
patterning said stopping layer and said low k dielectric layer to form a plurality of via holes for interconnects;
patterning said stopping layer and said low k dielectric layer to form a plurality of trenches for conductive lines;
forming a conformal blanket layer above the patterned layer of said stopping layer and said low k dielectric layer as a barrier layer;
forming a copper layer over said barrier layer to fill said via hole and said trench;
performing a first chemical mechanical polishing process to planarize said copper layer until said barrier layer;
performing a second chemical mechanical polishing process to remove said barrier layer until said stopping layer, and thereby said copper/low k dielectric dual damascene structure is formed;
performing a chemical buffing polishing process using a basic solution to remove said carbon-rich particles adhered on the exposed copper surface of said copper layer filled in said trench and said via hole; and
performing a post chemical mechanical polishing cleaning process.

2. The method of claim 1, wherein said low k dielectric layer is formed of spin-on polymer low k materials.

3. The method of claim 2, wherein said low k dielectric layer is formed of a spin-on polymer low k material selected from a group consisting of aromatic hydrocarbons, silk and flare.

4. The method of claim 1, wherein said stopping layer is formed of silicon nitride (Si₃N₄).

5. The method of claim 1, wherein said stopping layer is formed of silicon carbide.

6. The method of claim 1, wherein said barrier layer is formed of Ta.

7. The method of claim 1, wherein said barrier layer is formed of TaN.

8. The method of claim 1, wherein said copper layer is formed by a chemical vapor deposition method.

9. The method of claim 1, wherein said copper layer is formed by a physical vapor deposition method.

10. The method of claim 1, wherein said copper layer is formed by an electroplating method.

11. The method of claim 1, wherein said chemical buffing polishing process is performed using an alkaline basic solution.

12. The method of claim 1, wherein said chemical buffing polishing process is performed using a basic solution with a pH about 8 to 12.

13. The method of claim 12, wherein said chemical buffing polishing process is performed using a basic solution with a pH about 10.

14. The method of claim 1, wherein said chemical buffing polishing process is performed under a downward force of about 0.5 to 3 psi.

15. The method of claim 1, wherein said post chemical mechanical polishing cleaning process is performed using a basic solution.

16. The method of claim 1, wherein said post chemical mechanical polishing cleaning process is performed using a basic solution containing an organic amine compound and a quaternary ammonium hydroxide compound.

17. A method for removing carbon-rich particles adhered on the exposed copper surface of a copper/low k dielectric dual damascene structure, said method comprising:
providing a semiconductor substrate having a substructure comprising devices formed in said substrate and a metal layer formed thereon;
forming a low k dielectric layer over said substrate;
forming a stopping layer on said low k dielectric layer;
patterning said stopping layer and said low k dielectric layer to form a plurality of via holes for interconnects;
patterning said stopping layer and said low k dielectric layer to form a plurality of trenches for conductive lines;
forming a conformal blanket layer above the patterned layer of said stopping layer and said low k dielectric layer as a barrier layer;
forming a copper layer over said barrier layer to fill said via hole and said trench;
performing a first chemical mechanical polishing process to planarize said copper layer until said barrier layer;
performing a second chemical mechanical polishing process to remove said barrier layer until said stopping layer, and thereby said copper/low k dielectric dual damascene structure is formed;
performing a chemical buffing polishing process using an alkaline basic solution under a downward force of about 0.5 to 3 psi to remove said carbon-rich particles adhered on the exposed copper surface of said copper layer filled in said trench and said via hole; and
performing a post chemical mechanical polishing cleaning process using a basic solution containing an organic amine compound and a quaternary ammonium hydroxide compound.

18. The method of claim 17, wherein said low k dielectric layer is formed of spin-on polymer low k materials.

19. The method of claim 18, wherein said low k dielectric layer is formed of a spin-on polymer low k material selected from a group consisting of aromatic hydrocarbons, silk and flare.

20. The method of claim 17, wherein said stopping layer is formed of silicon nitride (Si₃N₄).

21. The method of claim 17, wherein said stopping layer is formed of silicon carbide.

22. The method of claim 17, wherein said barrier layer is formed of Ta.

23. The method of claim 17, wherein said barrier layer is formed of TaN.

24. The method of claim 17, wherein said copper layer is formed by a chemical vapor deposition method.

25. The method of claim 17, wherein said copper layer is formed by a physical vapor deposition method.

26. The method of claim 17, wherein said copper layer is formed by an electroplating method.

27. The method of claim 17, wherein said alkaline basic solution is with a pH about 8 to 12.

28. The method of claim 27, wherein said alkaline basic solution is with a pH about 10.
